(19) United States
(12) Patent Application Publication
(10) Pub. No.: US 2025/0138205 A1
(43) Pub. Date: May 1, 2025

(54) X-RAY DETECTOR

(71) Applicants: RAYENCE Co., Ltd., Gyeonggi-do (KR); VATECH EWOO Holdings Co., Ltd., Gyeonggi-do (KR); Qpix solutions Inc., Morrisville, NC (US)

(72) Inventors: Seungman YUN, Morrisville, NC (US); Jiuk KIM, Gyeonggi-do (KR); Gunha LEE, Gyeonggi-do (KR)

(73) Assignees: RAYENCE Co., Ltd., Gyeonggi-do (KR); VATECH EWOO Holdings Co., Ltd., Gyeonggi-do (KR); Qpix solutions Inc., Morrisville, NC (US)

(21) Appl. No.: 18/935,366

(22) Filed: Nov. 1, 2024

Related U.S. Application Data
(60) Provisional application No. 63/595,038, filed on Nov. 1, 2023.

(51) Int. Cl. G01T 1/24

(52) U.S. Cl. CPC G01T 1/244

(57) ABSTRACT

Proposed is an X-ray detector including a sensor panel configured to include first and second electrodes on a substrate, and a photoconductor layer between the first electrode and the second electrode, and a heating member located behind the sensor panel, wherein the photoconductor layer contains a ferroelectric material.

### CROSS REFERENCE TO RELATED APPLICATION

This application claims the benefit of the filing date of U.S. Patent Provisional Application No. 63/595,038, filed Nov. 1, 2023, as Attorney Docket No.: 810.0154prov, the teaches of which are incorporated herein their entirety by reference.

### BACKGROUND

### Technical Field

The present disclosure relates to an X-ray detector.

### Description of the Related Art

In recent years, digital detectors have become widely used for X-ray imaging.

Of two primary methods adopted for X-ray detection, direct-conversion detectors use a photoconductor that absorbs X-rays and directly creates electrical signals.

The problem is that repeated X-ray imaging may cause polarization in the photoconductor to persist for a long time and become fixed, resulting in a decrease in the sensitivity of X-ray detection.

### SUMMARY

Accordingly, the present disclosure has been made keeping in mind the above problems occurring in the related art, and the present disclosure is intended to provide a method to mitigate polarization in X-ray detectors.

In order to achieve the above objective, according to an aspect of the present disclosure, there is provided an X-ray detector including: a sensor panel including first and second electrodes on a substrate, and a photoconductor layer between the first electrode and the second electrode; and a heating member located behind the sensor panel, wherein the photoconductor layer may contain a ferroelectric material.

The ferroelectric material may be a perovskite.

According to an aspect of the present disclosure, there is provided an X-ray detector including: a sensor panel; a phosphor located in front of the sensor panel; and a heating member located behind the sensor panel.

The heating member may consist of a heating wire, and the heating wire may have a wrinkled shape or a mesh shape.

The X-ray detector may further include a driving board located behind the sensor panel, wherein the heating member may be provided on a front surface of the driving board.

The X-ray detector may have a driving sequence in which a standby section, a ready section, an integration section, and a readout section are repeated, wherein the heating member may perform a heating operation during at least part of the standby section.

A heating operation of the heating member may be stopped from the ready section to the readout section.

A heating temperature of the heating member may be 20 to 80 degrees.

The X-ray detector may further include a temperature sensor configured to detect temperature inside the X-ray detector, wherein when a temperature detected by the temperature sensor exceeds a set temperature, a heating operation of the heating member may be stopped.

According to the present disclosure, by disposing the heating member behind the sensor panel and operating the heating member, the photoconductor layer of the sensor panel can be heated.

Therefore, polarization in the photoconductor layer can be mitigated and the sensitivity decrease can be avoided.

Furthermore, the heating member allows moisture inside the X-ray detector to be removed, thereby preventing defects caused by moisture.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic view of an X-ray detector according to a first embodiment of the present disclosure;

FIG. 2 is a cross-sectional view schematically showing a sensor panel according to the first embodiment of the present disclosure;

FIG. 3 is a cross-sectional view schematically showing the X-ray detector equipped with a heating member according to the first embodiment of the present disclosure;

FIG. 4 is a plan view schematically showing an example of the heating member according to the first embodiment of the present disclosure;

FIG. 5 is a view schematically showing an example of heating timing of the heating member according to the first embodiment of the present disclosure;

FIG. 6 is a schematic view of an X-ray detector according to a second embodiment of the present disclosure;

FIG. 7 is a cross-sectional view schematically showing an X-ray detector equipped with a heating member according to a third embodiment of the present disclosure; and

FIG. 8 is a plan view schematically showing an example of the heating member according to the third embodiment of the present disclosure.

### DETAILED DESCRIPTION

Hereinafter, embodiments of the present disclosure will be described in detail with reference to the drawings.

### First Embodiment

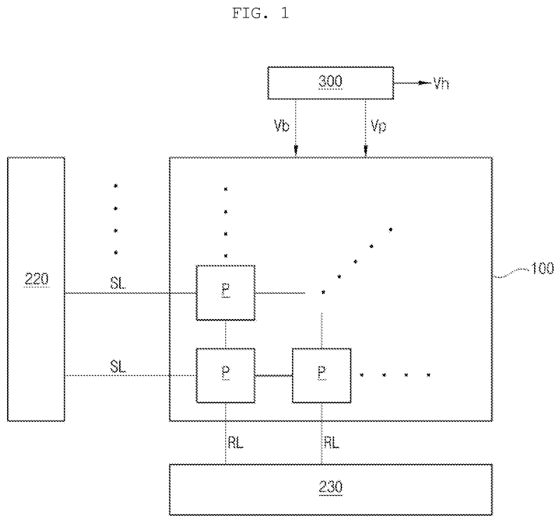

FIG. 1 is a schematic view of an X-ray detector according to a first embodiment of the present disclosure.

Referring to FIG. 1, an X-ray detector 10 according to a first embodiment of the present disclosure may be a direct-conversion X-ray detector provided with a photoconductor layer.

The X-ray detector 10 may include a sensor panel 100, a driving circuit part for driving the sensor panel 100, and a power circuit 300 that supplies a driving voltage (or power voltage) to drive the X-ray detector 10.

The sensor panel 100 may be a direct-conversion sensor panel 100 that directly converts incident X-rays into electrical signals.

Although not specifically shown, the sensor panel 100 may include: an active area, which is the area that actually receives and detects X-rays; and a non-active area located outside the active area.

In the active area, a pixel array composed of a plurality of pixels P is disposed on a substrate, and the pixels P may be arranged in a matrix form along a plurality of row lines and a plurality of column lines.

On the substrate of the sensor panel 100, a plurality of scan lines (or gate lines) SL extending along the row lines and a plurality of readout lines (or data lines) RL extending along the column lines may be disposed. The scan lines SL and the readout lines RL may be connected to corresponding pixels P.

Each pixel P may be provided with a photoconductive element that detects X-rays and generates a corresponding electrical signal.

The driving circuit part for driving the sensor panel 100 may include a scan circuit 220 and a readout circuit 230.

In this case, the scan circuit 220 sequentially scans the scan lines SL and applies a scan signal of a turn-on level. Accordingly, individual row line is sequentially selected, and data, which is an electrical signal stored in the pixel P located in the selected row line, may be output to the corresponding readout line RL. Then, the readout circuit 230 may receive the data stored in the pixel P through the readout line RL.

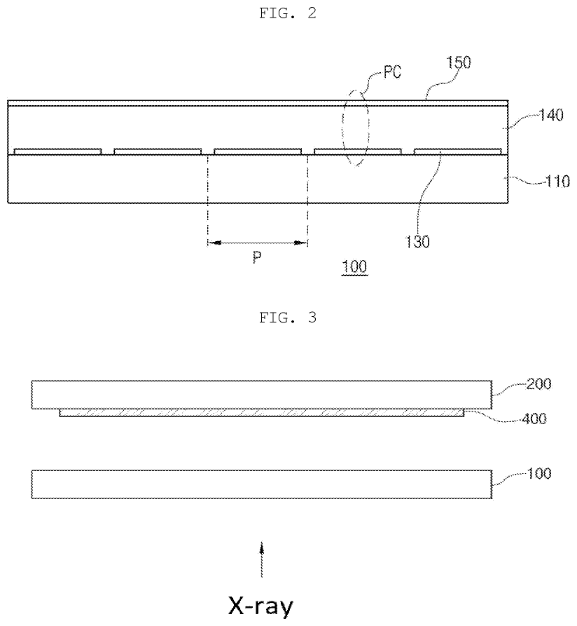

Meanwhile, the sensor panel 100 including the pixel p on which the photoconductive element is formed will be described with further reference to FIG. 2. FIG. 2 is a cross-sectional view schematically showing a sensor panel according to the first embodiment of the present disclosure.

The sensor panel 100 may include the photoconductive element PC formed in each pixel P on the substrate 110.

In this case, the substrate 110 may be configured as, but is not limited to, a CMOS substrate, a glass substrate, or a plastic substrate having flexible properties.

The photoconductive element PC provided in each pixel P may include: a first electrode (or pixel electrode) 130, which is a lower electrode provided on the substrate 110; a second electrode (or common electrode) 150, which is an upper electrode located above the first electrode 130; and a photoconductor layer 140 interposed between the first electrode 130 and the second electrode 150.

The first electrode 130 may be provided in a pixel-by-pixel pattern corresponding to each pixel P.

The photoconductor layer 140 provided on the first electrode 130 may be formed, for example, continuously along the pixels P substantially arranged in the active area. In other words, the photoconductor layer 140 may be formed corresponding to the pixels P arranged in the active area.

As a photoconductor forming the photoconductor layer 140, a ferroelectric material such as perovskite, for example, may be used, but is not limited thereto.

In this case, the perovskite is a material with a crystal structure following the formula ABX3, where A denotes a monovalent cation, B denotes a metal cation, and X may denote a halogen anion.

The perovskite may be, but is not limited to, CsPbBr3, Cs2AgBiBr6, MAPbI3, or MAPbBr3.

The photoconductor layer 140 of perovskite may be formed, for example, by a solution method of applying and curing a solution containing a perovskite powder, but is not limited thereto. As an example of the solution method, the photoconductor layer 140 of perovskite may be formed through a process of applying and curing a solution (or paste) containing a perovskite powder and a solvent onto the substrate 110 on which the first electrode 130 is provided.

The second electrode 150 provided on the photoconductor layer 140 may be formed, for example, continuously along the pixels P substantially arranged in the active area. In other words, the second electrode 150 may be formed corresponding to the pixels P arranged in the active area.

In order to implement charge generation due to photoelectric action in the photoconductive element PC configured as above, a pixel voltage Vp, which is a driving voltage (or first driving voltage), may be applied to the first electrode 130, and a bias voltage Vb, which is a driving voltage (or second driving voltage), may be applied to the second electrode 150. Accordingly, a difference voltage between the bias voltage Vb and the pixel voltage Vp is applied to the photoconductive element PC, and in this state, when X-rays are incident, corresponding charges are generated by photoelectric action, and the generated charges may be collected at the first electrode 130.

The driving voltage may be generated and provided by the power circuit 300. In this regard, the power circuit 300 may generate the pixel voltage Vp and the bias voltage Vb and output the pixel voltage Vp and the bias voltage Vb to the sensor panel 100.

At this time, in the embodiment, an example is given where the bias voltage Vb has a higher potential than the pixel voltage Vp. For example, the pixel voltage Vp may be a ground voltage or a voltage of positive potential (e.g., 1.2 to 2.2 V), and in the case of the photoconductor layer 140 of perovskite, the bias voltage Vb may be a voltage of positive potential higher than the pixel voltage Vp (e.g., over 3 V).

In this regard, the perovskite has a short carrier lifetime, enabling stable operation even at lower driving voltages compared to photoconductors such as a-Se and CdTe, and thus the bias voltage Vb may have a value of 0.01 to 0.1 V per (μm) of the photoconductor layer 140 of perovskite, that is, 0.01 to 0.1 V/μm.

Meanwhile, in the embodiment, in order to prevent polarization from being fixed in the photoconductor layer 140, the X-ray detector 10 may be provided with a heating member that heats the photoconductor layer 140. By heating the photoconductor layer 140 to a certain temperature using the heating member, spontaneous polarization may be lost due to thermal fluctuations generation in an electric dipole of the photoconductor, thereby mitigating the polarization.

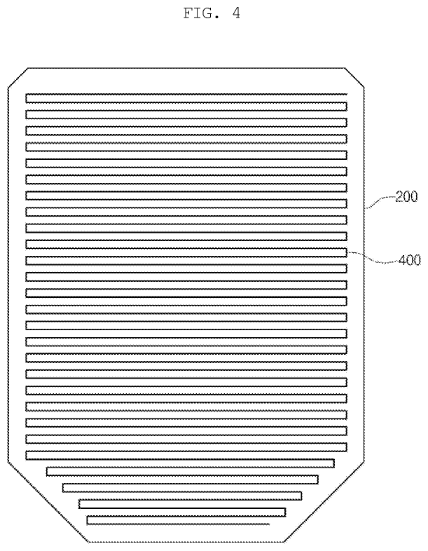

The X-ray detector 10 provided with the heating member will be described with reference to FIGS. 3 and 4. FIG. 3 is a cross-sectional view schematically showing the X-ray detector equipped with a heating member according to the first embodiment of the present disclosure, and FIG. 4 is a plan view schematically showing an example of the heating member according to the first embodiment of the present disclosure.

Referring to FIGS. 3 and 4 along with FIGS. 1 and 2, the X-ray detector 10 may include the sensor panel 100, a driving board 200, and a heating member 400.

The sensor panel 100 may be disposed in front of the driving board 200. In other words, the sensor panel 100 may be located in the direction of x-ray emission.

The driving board 200 may be disposed behind the sensor panel 100. In other words, the driving board 200 100 may be located on the back of the substrate 110 of the sensor panel 100.

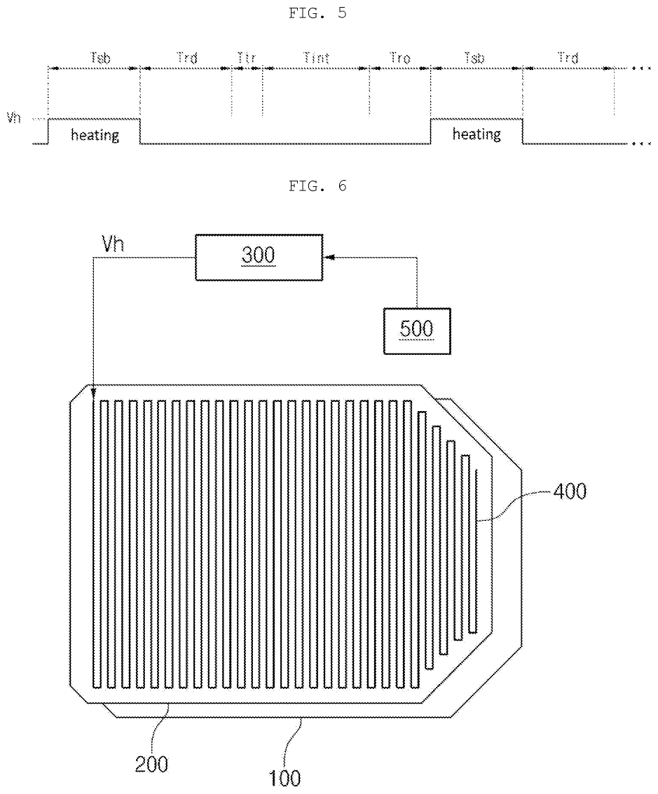

On the driving board 200, for example, a driving circuit part for driving the sensor panel 100 may be disposed, and furthermore, a power circuit (see 300 in FIG. 6, hereinafter the same) may be disposed. These circuit configurations may be mounted, for example, on the rear side of the driving board 200.

The heating member 400 may be located behind the sensor panel 100 (or the substrate 110). In this regard, for example, the heating member 400 may be disposed between the sensor panel 100 and the driving board 200. In this embodiment, the case where the heating member 400 is provided on the front surface of the driving board 200 is taken as an example.

As another example, the heating member 400 may be provided on the rear surface of the driving board 200, or the heating member 400 may be provided separately from the driving board 200 on the rear surface of the driving board 200.

As described above, as the heating member 400 is located behind the sensor panel 100, the actual effect of the heating member 400 on X-ray detection in the sensor panel 100 may be minimized.

The heating member 400 may be made of a high-resistance metal material to dissipate heat, for example, but is not limited thereto.

The heating member 400 may, for example, consist of a heating wire as shown in FIG. 4. In this way, the heating member 400 composed of a heating wire may be, for example, bent multiple times on both sides thereof to form a wrinkled shape when viewed as a whole. As another example, the heating member 400 composed of a heating wire may be formed in a mesh shape.

The heating member 400 may be provided corresponding to the active area of the sensor panel 100 where the photoconductor layer 140 is formed in order to mitigate polarization in the photoconductor layer 140.

Meanwhile, power (or heating power) Vh for driving the heating member may be generated and provided in the power circuit 300.

During the heating operation of the heating member 400, the temperature of the heating member 400 may be, for example, approximately 20 to 80 degrees, and preferably approximately 40 to 70 degrees.

The heating temperature of the heating member 400 may be set above the phase transition temperature by taking into account the phase transition of temperature perovskite as a photoconductor. In addition, the heating temperature of the heating member 400 may be set in consideration of defects that may occur in the sensor panel 100 by heating and of the usage environment of the X-ray detector (for example, if the X-ray detector is an intraoral sensor, insertion into the oral cavity), etc.

Meanwhile, the heating time of the heating member 400 may be set to minimize the effect of heating on X-ray detection. In this regard, FIG. 5 may be referred to. FIG. 5 is a view schematically showing an example of heating timing of the heating member according to the first embodiment of the present disclosure.

Referring to FIG. 5, the driving sequence of the X-ray detector 10 may include, for example, a standby section Tsb, a ready section Trd, a trigger section Ttr, an integration section Tint, and a readout section Tro, and this series of sections may be repeated.

In this case, the heating operation of the heating member 400 may be performed during at least part of the standby section Tsb. The standby section Tsb may actually correspond to a section in which the operation of the X-ray detector 10, to be specific, of the sensor panel 100 is stopped. The heating operation of the heating member may be performed within the standby section Tsb. As a result, the sensor panel 100 (to be specific, photoconductor layer 140) may be heated without substantial effect on X-ray detection.

When the ready section Trd starts by a ready signal after the standby section Tsb ends, in response to the ready signal, the supply of the power Vh from the power circuit 300 to the heating member 400 may be stopped and the heating operation of the heating member 400 may be stopped. Such power supply interruption may last until the next standby section Tsb, that is, the heating operation of the heating member 400 may be stopped from the ready section Trd to the readout section Tro.

When the next standby section Tsb starts after the readout section Tro ends, the power Vh is applied to the heating member 400 and the heating operation may be performed again.

As previously mentioned, in this embodiment, the heating member 400 is disposed behind the sensor panel 100, and by operating the heating member 400, the photoconductor layer 140 of the sensor panel 100 may be heated.

As a result, polarization in the photoconductor layer 140 may be mitigated and a decrease in the sensitivity may be avoided.

Furthermore, moisture inside the X-ray detector 10 may be removed by means of the heating member 400, thereby preventing defects caused by moisture. In particular, since the photoconductor layer 140 is vulnerable to moisture, by removing moisture by heating of the heating member 400, defects caused by moisture may be prevented.

### Second Embodiment

FIG. 6 is a schematic view of an X-ray detector according to a second embodiment of the present disclosure.

Hereinafter, detailed description of the same and similar configuration as the above-described first embodiment may be omitted.

An X-ray detector 10 of the second embodiment may include a temperature sensor 500 in addition to the components of the X-ray detector of the first embodiment described above.

The temperature sensor 500 built into the X-ray detector 10 may detect the temperature inside the X-ray detector 10.

By using the temperature sensor 500 in this way, in case the X-ray detector 10 overheats due to the operation of the heating member 400, overheating of the X-ray detector 10 may be detected and the operation of the heating member 400 may be stopped.

In this regard, for example, the temperature sensor 500 detects the internal temperature of the X-ray detector 10 in real time, and provides a detection result signal (or stop signal) to the power circuit 300 (or driving circuit part) when detecting a temperature exceeding a set temperature (or reference temperature) that may cause a defect.

The power circuit 300 may interrupt the supply of the power Vh to the heating member 400 in response to the detection result signal provided by the temperature sensor 500. Accordingly, the heating operation of the heating member 400 is stopped, and as a result, a defect of the X-ray detector 10 due to overheating may be prevented.

Meanwhile, the temperature sensor 500 may be disposed at a variety of points inside the X-ray detector 10. For example, the temperature sensor 500 may be placed between the sensor panel 100 and the heating member 400, at the rear of the heating member 400 (for example, on the rear side of the driving board 200), on the side of the heating member 400, or in the non-active area of the sensor panel 100.

### Third Embodiment

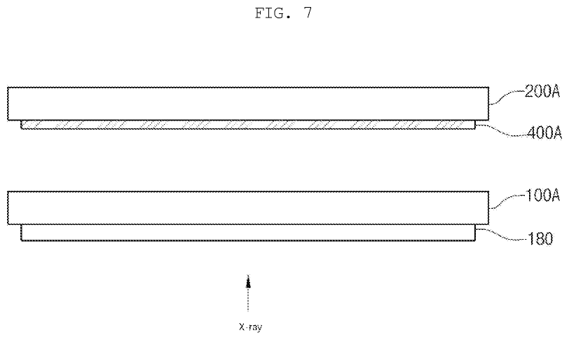

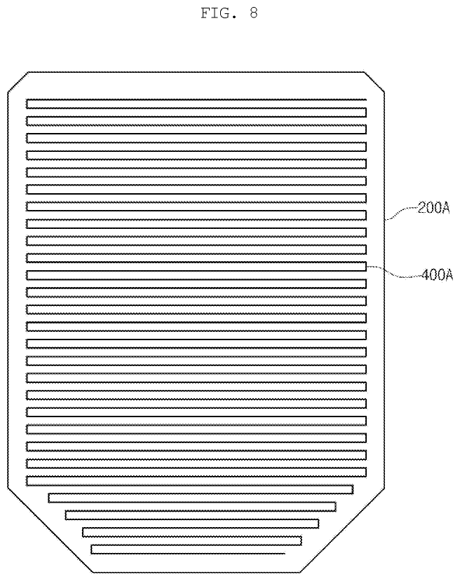

FIG. 7 is a cross-sectional view schematically showing an X-ray detector equipped with a heating member according to a third embodiment of the present disclosure, and FIG. 8 is a plan view schematically showing an example of the heating member according to the third embodiment of the present disclosure.

Hereinafter, detailed description of the same and similar configuration as the above-described first and second embodiments may be omitted.

Referring to FIGS. 7 and 8, an X-ray detector 10A of the third embodiment may be an indirect-conversion X-ray detector unlike the case of the first and second embodiments.

The indirect-conversion X-ray detector 10A may include: an indirect-conversion sensor panel 100A; a phosphor 180 located in front of the sensor panel 100A; a driving board 200A located behind the sensor panel 100A; and a heating member 400A located behind the sensor panel 100A.

The phosphor 180 is located in front of the sensor panel 100A and may convert emitted X-rays into visible light. The phosphor 180 may be, for example, formed of CsI, but is not limited thereto.

In the sensor panel 100A, a pixel array composed of a plurality of pixels may be disposed in an active area, similar to the first embodiment described above. Each pixel may be provided with a photoconductive element that detects visible light emitted from the phosphor 180 and generates a corresponding electrical signal.

The photoconductive element may include: a first electrode formed on a substrate; a photoconductor layer formed on the first electrode; and a second electrode formed on the photoconductor layer. In this case, the photoconductor layer may generate electric charges depending on the incident visible light.

Similar to the first embodiment, the heating member 400A may be located behind the sensor panel 100A (or substrate). In this regard, for example, the heating member 400A may be disposed between the sensor panel 100A and the driving board 200A. In this embodiment, the case where the heating member 400A is provided on the front surface of the driving board 200A is taken as an example.

As another example, the heating member 400A may be provided on the rear surface of the driving board 200A, or the heating member 400A may be provided separately from the driving board 200A on the rear surface of the driving board 200A.

As described above, as the heating member 400A is located behind the sensor panel 100A, the actual effect of the heating member 400A on x-ray detection in the sensor panel 100A may be minimized.

The heating member 400A may be made of a high-resistance metal material to dissipate heat, for example, but is not limited thereto.

The heating member 400A may, for example, consist of a heating wire as shown in FIG. 8. In this way, the heating member 400A composed of a heating wire may be, for example, bent multiple times on both sides thereof to form a wrinkled shape when viewed as a whole. As another example, the heating member 400A composed of a heating wire may be formed in a mesh shape.

The heating member 400A of this embodiment may compensate for the defects of phosphor 180 that is vulnerable to moisture. Due to the heating operation of the heating member 400A, moisture inside the X-ray detector 10A may be removed, and as a result, the defects of the phosphor 180 caused by moisture may be compensated for. The heating member 400A may be may be formed corresponding to the phosphor 180.

During the heating operation of the heating member 400A, the temperature of the heating member 400A may be, for example, approximately 20 to 80 degrees, similar to the first embodiment, and preferably approximately 40 to 70 degrees.

The heating time of the heating member 400A may be set to minimize the effect of heating on X-ray detection.

In this regard, for example, similar to the first embodiment, the heating operation of the heating member 400A may be performed during at least part of the standby section. When the ready section starts by a ready signal after the standby section ends, in response to the ready signal, the supply of the power from the power circuit to the heating member 400A may be stopped and the heating operation of the heating member 400A may be stopped. When the next standby section starts after the readout section ends, the power is applied to the heating member 400A and the heating operation may be performed again.

As described above, in this embodiment, by disposing the heating member 400A behind the sensor panel 100A, and operating the heating member 400A to heat the phosphor 180, moisture may be removed.

As a result, the defects of the phosphor 180 caused by moisture may be prevented.

Meanwhile, similar to the second embodiment, the X-ray detector 10A of this embodiment may further include a temperature sensor.

The above-described embodiment of the present disclosure is an example of the present disclosure, and free modification is possible within the scope included in the spirit of the present disclosure. Accordingly, the present disclosure includes modifications of the present disclosure within the scope of the appended claims and the equivalents thereof.

What is claimed is:

1. An X-ray detector comprising:
a sensor panel configured to include first and second electrodes on a substrate, and a photoconductor layer between the first electrode and the second electrode; and
a heating member located behind the sensor panel,
wherein the photoconductor layer contains a ferroelectric material.

2. The X-ray detector of claim 1, wherein the ferroelectric material is a perovskite.

3. The X-ray detector of claim 1, wherein the heating member consists of a heating wire, and
the heating wire has a wrinkled shape or a mesh shape.

4. The X-ray detector of claim 1, further comprising:
a driving board located behind the sensor panel,
wherein the heating member is provided on a front surface of the driving board.

5. The X-ray detector of claim 1, wherein the X-ray detector has a driving sequence in which a standby section, a ready section, an integration section, and a readout section are repeated,
wherein the heating member performs a heating operation during at least part of the standby section.

6. The X-ray detector of claim 5, wherein a heating operation of the heating member is stopped from the ready section to the readout section.

7. The X-ray detector of claim 1, wherein a heating temperature of the heating member is 20 to 80 degrees.

8. The X-ray detector of claim 1, further comprising:
a temperature sensor configured to detect temperature inside the X-ray detector,
wherein when a temperature detected by the temperature sensor exceeds a set temperature, a heating operation of the heating member is stopped.
